(19) United States
(12) Patent Application Publication
(10) Pub. No.: US 2025/0233506 A1
(43) Pub. Date: Jul. 17, 2025

(54) ZERO-CROSSING DETECTION CIRCUIT, WIRELESS RECEIVER, AND SWITCHING POWER SUPPLY

(71) Applicant: Zhuhai Nanxin Semiconductor Technology Co., Ltd, Zhuhai City (CN)

(72) Inventor: Lixu Gao, Zhuhai City (CN)

(21) Appl. No.: 19/022,750

(22) Filed: Jan. 15, 2025

(30) Foreign Application Priority Data
Jan. 15, 2024 (CN) 202410060346.4

(51) Int. Cl. H02M 1/08; G01R 19/00; G01R 19/25; H02J 50/12; H02M 1/00; H02M 3/158

(52) U.S. Cl. CPC H02M 1/083; G01R 19/0038; G01R 19/25; H02J 50/12; H02M 1/0012; H02M 1/0025; H02M 3/158

(57) ABSTRACT

A comparator detection circuit acquires a turn-off control signal based on a precision reference voltage, and outputs the turn-off control signal to a logic control circuit, such that the logic control circuit acquires an enable signal based on the turn-off control signal. The logic control circuit transmits the enable signal to a precision reference voltage adjustment circuit, such that the precision reference voltage adjustment circuit acquires, under an effect of the enable signal, an adjustment signal based on changes of the voltage to be measured upon completion of turn-off of the power transistors. The precision reference voltage adjustment circuit transmits the adjustment signal to the comparator detection circuit, such that the comparator detection circuit changes the precision reference voltage based on the adjustment signal. As such, a reference point of the comparator detection circuit within the subsequent clock is adjusted, and the accuracy of the turn-off control signal is improved.

### CROSS-REFERENCE TO RELATED APPLICATION

This application is based upon and claims the priority of Chinese Patent Application No. 202410060346.4, filed on Jan. 15, 2024, the entire content of which is hereby incorporated by reference herein and made a part of this specification.

### TECHNICAL FIELD

The present disclosure relates to the technical field of detection, and in particular, relates to a zero-crossing detection circuit, a wireless receiver, and a switching power supply.

### BACKGROUND

In a wireless charging receiving circuit, turn-off of power transistors of a rectifier is controlled based on a zero crossing detection (ZCD) function. The wireless charging receiver circuit includes a rectifier and a receive coil. Since the ZCD function is generally implemented using a ZCD comparator, the more precise an output signal of the ZCD comparator, the more timing accurate the turn-off of the power switches. This reduces the likelihood of backflow in the current of the receive coil, thereby improving the stability of the rectifier.

However, in the related arts, the ZCD comparator exhibits transient delays, and consequently the output signal is not sufficiently precise. This leads to inaccurate turn-off timings of the power switches, which in turn causes poor stability of the rectifier.

### SUMMARY

The present disclosure provides a zero-crossing detection circuit, a chip, a wireless receiver, a switching power supply, and an electronic device, which are capable of improving accuracy of an output signal of a ZCD comparator, achieving accurate turn-off timings of power transistors, and preventing stability issues of a rectifier.

In a first aspect, some embodiments of the present disclosure provide a zero-crossing detection circuit, applicable to a wireless charging receiver or a switching power supply. The wireless charging receiver or the switching power supply includes a power transistor. The zero-crossing detection circuit includes a comparator detection circuit, a precision reference voltage adjustment circuit, and a logic control circuit.

A first input terminal of the comparator detection circuit is configured to receive a precision reference voltage, a second input terminal of the comparator detection circuit is configured to receive a voltage to be measured in response to turn-on of the power transistor of a wireless charging receiver or a switching power supply, an input terminal of the precision reference voltage adjustment circuit is configured to receive a voltage to be measured upon completion of turn-off of the power transistor, an output terminal of the comparator detection circuit is electrically connected to an input terminal of the logic control circuit, an output terminal of the logic control circuit is electrically connected to a control terminal of the precision reference voltage adjustment circuit, and an output terminal of the precision reference voltage adjustment circuit is electrically connected to the first input terminal of the comparator detection circuit.

The comparator detection circuit is configured to, with respect to two adjacent clock cycles, acquire a turn-off control signal within a preceding clock cycle of the two adjacent clock cycles based on a precision reference voltage within the preceding clock cycle and the voltage to be measured in response to turn-on of the power transistor, and transmit the turn-off control signal within the preceding clock cycle to the logic control circuit, wherein the turn-off control signal within the preceding clock cycle is used for controlling the power transistor to be turned off.

The logic control circuit is configured to acquire an enable signal within the preceding clock cycle based on the turn-off control signal within the preceding clock cycle, and transmit the enable signal within the preceding clock cycle to the precision reference voltage adjustment circuit.

The precision reference voltage adjustment circuit is configured to, under an effect of the enable signal within the preceding clock cycle, acquire an adjustment signal within a subsequent clock cycle of the two adjacent clock cycles based on changes of the voltage to be measured upon completion of turn-off of the power transistor, and transmit the adjustment signal within the subsequent clock cycle to the comparator detection circuit.

The comparator detection circuit is configured to adjust the precision reference voltage within the preceding clock cycle based on the adjustment signal within the subsequent clock cycle to acquire a precision reference voltage within the subsequent clock cycle, and acquire a turn-off control signal within the subsequent clock cycle based on the precision reference voltage within the subsequent clock cycle and the voltage to be measured in response to turn-on of the power transistor, wherein the turn-off control signal within the subsequent clock cycle is used for controlling the power transistor to be turned off.

In the zero-crossing detection circuit according to the first aspect, the comparator detection circuit is capable of acquiring, with respect to two adjacent clock cycles, a turn-off control signal within a preceding clock cycle based on a precision reference voltage within the preceding clock cycle and the voltage to be measured in response to turn-on of the power transistor, and transmitting the turn-off control signal within the preceding clock cycle to the logic control circuit, such that the logic control circuit acquires the enable signal within the preceding clock cycle based on the turn-off control signal within the preceding clock cycle. In this way, the logic control circuit is capable of transmitting the enable signal within the preceding clock cycle to the precision reference voltage adjustment circuit, such that the precision reference voltage adjustment circuit acquires, under an effect of the enable signal within the preceding clock cycle, an adjustment signal within a subsequent clock cycle based on changes of the voltage to be measured upon completion of turn-off of the power transistors. Hence, the precision reference voltage adjustment circuit is capable of transmitting the adjustment signal within the subsequent clock cycle to the comparator detection circuit, such that the comparator detection circuit changes the precision reference voltage within the preceding clock cycle based on the adjustment signal within the subsequent clock cycle and acquires the precision reference voltage within the subsequent clock cycle. As such, a reference point of the comparator detection circuit within the subsequent clock is adjusted, such that the accuracy of the turn-off control signal within the subsequent clock cycle is improved. In this way, the turn-off timings of the power transistors are adjusted to be closest to the precision turn-off timing.

In some embodiments, the precision reference voltage adjustment circuit includes a switch assembly, a voltage sampling circuit, a reference circuit, a comparator circuit, and a logic processing circuit.

A first terminal of the switch assembly is configured receive the voltage to be measured upon completion of the power transistor, a control terminal of the switch assembly is electrically connected to the output terminal of the logic control circuit, a second terminal of the switch assembly is electrically connected to a first input terminal of the comparator circuit, a first terminal of the voltage sampling circuit is electrically connected between the second terminal of the switch assembly and the first input terminal of the comparator circuit, a second terminal of the voltage sampling circuit and a first terminal of the reference circuit are both grounded, a second terminal of the reference circuit is electrically connected to a second input terminal of the comparator circuit, an output terminal of the comparator circuit is electrically connected to an input terminal of the logic processing circuit, and an output terminal of the logic processing circuit is electrically connected to the first input terminal of the comparator detection circuit.

The logic control circuit is configured to transmit the enable signal within the preceding clock cycle to the switch assembly, wherein the switch assembly is turned on under the effect of the enable signal within the preceding clock cycle.

The voltage sampling circuit is configured to, upon turn-on of the switch assembly, sample the voltage to be measured upon completion of turn-off of the power transistor to acquire a sampled voltage, transmit the sampled voltage to the comparator circuit, wherein the sampled voltage is related to the voltage to be measured upon completion of turn-off of the power transistor.

The reference circuit is configured to transmit a reference voltage to the comparator circuit, wherein the reference voltage is used for determining whether the power transistor is turned off on time in response to the turn-off control signal within the preceding clock cycle.

The comparator circuit is configured to acquire a digital signal based on the sampled voltage and the reference voltage, and transmit the digital signal to the logic processing circuit.

The logic processing circuit is configured to generate the adjustment signal within the subsequent clock cycle based on the digital signal.

In some embodiments, the logic control circuit is configured to increase the precision reference voltage within the preceding clock cycle using the adjustment signal within the subsequent clock cycle in a case that the digital signal indicates that the voltage to be measured upon completion of turn-off of the power transistor is greater than the reference voltage.

Alternatively, the logic control circuit is configured to decrease the precision reference voltage within the preceding clock cycle using the adjustment signal within the subsequent clock cycle in a case that the digital signal indicates that the voltage to be measured upon completion of turn-off of the power transistor is less than the reference voltage.

In some embodiments, the comparator circuit includes a comparator.

A first input terminal of the comparator is electrically connected to an output terminal of the voltage sampling circuit, a second input terminal of the comparator is electrically connected to the second terminal of the reference circuit, and an output terminal of the comparator is electrically connected to the input terminal of the logic processing circuit.

In some embodiments, the voltage sampling circuit includes a first capacitor; wherein a first terminal of the first capacitor is electrically connected between the second terminal of the switch assembly and the first input terminal of the comparator circuit, and a second terminal of the first capacitor is grounded.

In some embodiments, the comparator detection circuit includes a zero-crossing detection comparator; wherein a first input terminal of the zero-crossing detection comparator is configured to receive the precision reference voltage, a second input terminal of the zero-crossing detection comparator is configured to receive the voltage to be measured in response to turn-on of the power transistor, and an output terminal of the zero-crossing detection comparator is electrically connected to the input terminal of the logic control circuit.

In a second aspect, some embodiments the present disclosure provide a wireless charging receiver. The wireless charging receiver includes a receiver circuit, a rectifier circuit, and the zero-crossing detection circuit according to the first aspect.

A first output terminal of the receiver circuit is electrically connected to a first input terminal of the rectifier circuit, a second output terminal of the receiver circuit is electrically connected to a second input terminal of the rectifier circuit, the second input terminal of the comparator detection circuit and the input terminal of the precision reference adjustment circuit are both electrically connected between the first output terminal of the receiver circuit and the first input terminal of the rectifier circuit or between the second output terminal of the receiver circuit and the second input terminal of the rectifier circuit, and the output terminal of the comparator detection circuit is electrically connected to a control terminal of the rectifier circuit;

The receiver circuit includes a receive coil coupled to a transmit coil, and is configured to receive an alternating current (AC) voltage via the receive coil, and transmit the AC voltage to the rectifier circuit.

The rectifier circuit is configured to convert the AC voltage to a direct current (DC) voltage.

The zero-crossing detection circuit is configured to acquire the voltage to be measured from the rectifier circuit; and in a case that the a current at the first input terminal or the second input terminal of the rectifier circuit is less than a predetermined current, acquire a turn-off control signal based on the precision reference voltage and the voltage to be measured, and turn off part of power transistors in the rectifier circuit based on the turn-off control signal; wherein the voltage to be measured comprises a difference between a zero voltage and a voltage at the first input terminal of the rectifier circuit or a difference between the zero voltage and a voltage at the second input terminal of the rectifier circuit.

In a third aspect, the present disclosure provides a switching power supply. The switching power supply includes an operational amplifier circuit, a pulse width modulation comparator circuit, a control circuit, a first driver circuit, a second driver circuit, a high-side power transistor, a low-side power transistor, a freewheeling inductor, a second capacitor, and the zero-crossing detection circuit according to the first aspect.

A first input terminal of the operational amplifier circuit is configured receive a reference signal, a second input terminal of the operational amplifier circuit is configured receive a feedback signal, an output terminal of the operational amplifier circuit is electrically connected to a first input terminal of the pulse width modulation comparator circuit, a second terminal of the pulse width modulation comparator circuit is configured to receive a triangle wave signal, an output terminal of the pulse width modulation comparator circuit and the output terminal of the comparator detection circuit are both electrically connected to an input terminal of the control circuit, an output terminal of the control circuit is electrically connected to an input terminal of the first driver circuit and an input terminal of the second driver circuit, an output terminal of the first driver circuit is electrically connected to a control terminal of the high-side power transistor, an output terminal of the second driver circuit is electrically connected to a control terminal of the low-side power transistor, a first terminal of the high-side power transistor is configured to receive a power supply voltage, a second terminal of the high-side power transistor is electrically connected to a first terminal of the low-side power transistor, the second input terminal of the comparator detection circuit, the input terminal of the precision reference voltage adjustment circuit, and a first terminal of the freewheeling inductor are all electrically connected between the second terminal of the high-side power transistor and the first terminal of the low-side power transistor, a second terminal of the freewheeling inductor is electrically connected to a first terminal of the second capacitor, and a second terminal of the low-side power transistor and a second terminal of the second capacitor are both grounded.

The operational amplifier circuit is configured to transmit an output signal of the operational amplifier circuit to the pulse width modulation comparator circuit based on the reference signal and the feedback signal.

The pulse width modulation comparator circuit is configured to transmit a pulse width modulation signal to the control circuit based on the output signal of the operational amplifier circuit and the triangle wave signal.

The zero-crossing detection circuit is configured to acquire the voltage to be measured from the high-side power transistor or the low-side power transistor, and transmit a turn-off control signal to the control circuit based on the precision reference voltage and the voltage to be measured, wherein the voltage to be measured comprises a difference between a voltage at the second terminal of the high-side power transistor and a zero voltage or a difference between a voltage at the first terminal of the low-side power transistor and the zero voltage.

The control circuit is configured to transmit a turn-on or turn off control signal to the first driver circuit and the second driver circuit based on the pulse width modulation signal and the turn-off control signal.

The first driver circuit is configured to control turn-on or turn-off of the high-side power transistor based on the turn-on or turn-off control signal.

The second driver circuit is configured to control turn-on or turn-off of the low-side power transistor based on the turn-on or turn-off control signal.

In a fourth aspect, the present disclosure provides a chip. The chip includes the zero-crossing detection circuit according to the first aspect; or the wireless charging receiver according to the second aspect; or the switching power supply according to the third aspect.

In a fifth aspect, the present disclosure provides an electronic device. The electronic device includes the chip according to the fourth aspect.

### BRIEF DESCRIPTION OF THE DRAWINGS

FIG. 1 is a schematic structural diagram of a zero-crossing detection circuit in the related art;

FIG. 2 is a schematic diagram of an operating waveform of a zero-crossing detection circuit in the related art;

FIG. 3 is a schematic structural diagram of a zero-crossing detection circuit in the related art;

FIG. 4 is a schematic diagram of an operating waveform of a zero-crossing detection circuit in the related art;

FIG. 5 is a schematic structural diagram of a switching power supply according to some embodiments of the present disclosure;

FIG. 6 is a schematic structural diagram of a wireless charging receiver according to some embodiments of the present disclosure.

FIG. 7 is a schematic structural diagram of a zero-crossing detection circuit according to some embodiments of the present disclosure;

FIG. 8 is a schematic structural diagram of a zero-crossing detection circuit according to some embodiments of the present disclosure; and

FIG. 9 is a schematic flowchart of an operating waveform of a zero-crossing detection circuit according to some embodiments of the present disclosure.

### DETAILED DESCRIPTION

In the present disclosure, the term “at least one” refers to one or more than one, and the term “a plurality of” refers to two or more than two. The term “and/or” is merely an association relationship for describing associated objects, which represents that there may exist three types of relationships, for example, A and/or B may represent three situations: only A exists, both A and B exist, and only B exists, wherein A and B may be single or plural. In addition, the symbol “/” generally represents an “or” relationship between associated objects before and after the symbol. The expression “at least one of the following” or the like expression means any combination of the items or options listed, including a single item or option or any combination of plural items or options listed. For example, at least one of a single a, a single b, and a single c may indicate: the single a, the single b, the single c, a combination of a and b, a combination of a and c, a combination of b and c, or a combination of a, b, and c, wherein each of a, b, and c may be single or plural. In addition, the terms “first,” “second,” and the like are merely for the illustration purpose, and shall not be construed as indicating or implying a relative importance.

In the description of the present disclosure, it should be understood that the terms “central,” “transversal,” “longitudinal,” “upper,” “lower,” “left,” “right,” “front,” “rear,” and the like indicate orientations and position relationships which are based on the illustrations in the accompanying drawings, and these terms are merely for ease and brevity of the description, instead of indicating or implying that the devices or elements shall have a particular orientation and shall be structured and operated based on the particular orientation. Accordingly, these terms shall not be construed as limiting the present disclosure.

In the description of the present disclosure, unless otherwise explicitly specified and defined, the terms “connected,” “coupled,” and derivatives forms thereof shall be understood in a broad sense. For example, the terms “connected,” “coupled,” and derivatives form thereof for depicting the circuit structure, in addition to physical connection, may also be understood as electrical connections or signal connection. The connection, for example, may be direct connection, i.e., the physical connection or, indirect connection via at least one intermediate element as long as the circuit is conducted, or communication between the interiors of two elements. The signal connection, in addition to signal connection via a circuitry, may also be signal connection via a communication medium, for example, radio waves. Persons of ordinary skill in the art may understand specific meanings of the above terms in the present disclosure according to the actual circumstances and contexts.

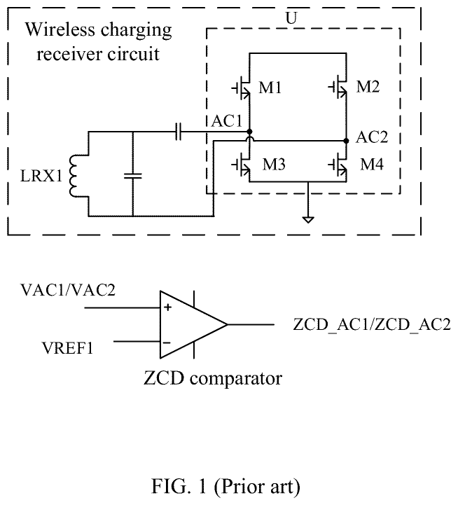

FIG. 1 is a schematic structural diagram of a zero-crossing detection circuit in the related art. As illustrated in FIG. 1, in a wireless charging receiver circuit, an output signal of a ZCD comparator is used as a turn-off signal for a power transistor M1, a power transistor M2, a power transistor M3, and a power transistor M4 in a rectifier U. The output signal of the ZCD comparator is acquired based on a first voltage and a first reference voltage VREF1. The first voltage is VAC1 or VAC2, and the first reference voltage VREF1 is a zero voltage. In the case that an output signal ZCD_AC1 of the ZCD comparator is a turn-off signal for the power transistor M2 and the power transistor M3, the first voltage is VAC1. In the case that an output signal ZCD_AC2 of the ZCD comparator is a turn-off signal for the power transistor M1 and the power transistor M4, the first voltage is VAC2.

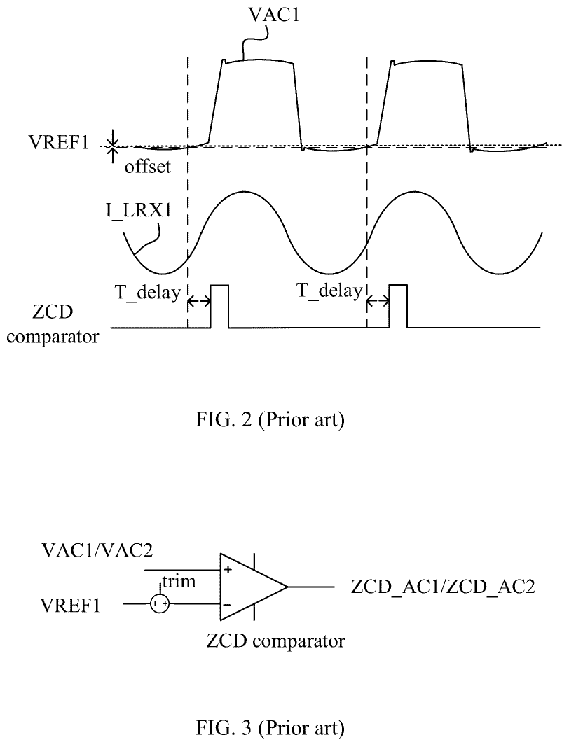

FIG. 2 illustrates a schematic diagram of an operating waveform of the zero-crossing detection circuit in FIG. 1. As illustrated in FIG. 2, since the ZCD comparator is subject to a static offset (offset) and a transient delay (T_delay), the turn-off timings of the power transistor M3 and the power transistor M4 are not accurate. Therefore, a current T_LRX1 of a receive coil may flow back, which potentially cause stability issues in the rectifier U.

FIG. 3 is a schematic structural diagram of a zero-crossing detection circuit in the related art. As illustrated in FIG. 3, a value of the first reference voltage VREF1 is adjusted using a trimmer to eliminate the static offset of the ZCD comparator. However, with this scheme, the transient delay T_delay of the ZCD comparator still fails to be eliminated.

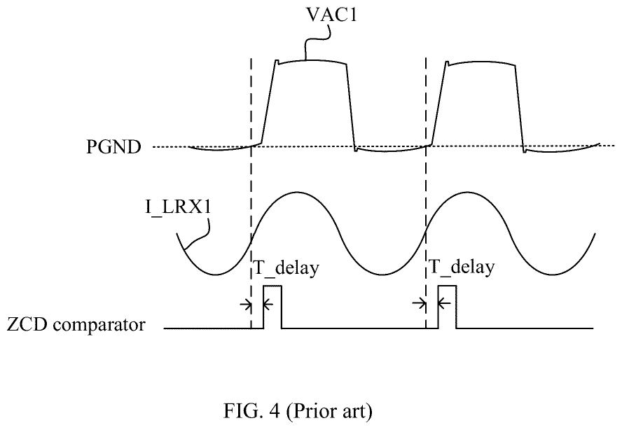

FIG. 4 illustrates a schematic diagram of an operating waveform of the zero-crossing detection circuit in FIG. 3. As illustrated in FIG. 4, even though the static offset of the ZCD comparator is eliminated using the trimmer, the transient delay T_delay of the ZCD comparator is still present. Therefore, the turn-off timings of the power transistor M3 and the power transistor M4 are still not sufficiently accurate, and thus the current T_LRX1 of the receive coil may flow back, which potentially cause stability issues in the rectifier U.

To solve the above problem, some embodiments of the present disclosure provide a zero-crossing detection circuit, a chip, a wireless receiver, a switching power supply, and an electronic device.

The zero-crossing detection circuit, the wireless receiver, the switching power supply may be chips or circuit modules.

The zero-crossing detection circuit according to the embodiments of the present disclosure is applicable to the switching power supply, the wireless charger, or the like electronic device having the zero-crossing detection function.

The electronic device may include, but is not limited to, a smart phone, a smart watch, or a TV set.

The switching power supply may be a buck switching power supply or a boost switching power supply, or may be a buck-boost switching power supply, which is not limited in the embodiments of the present disclosure. For ease of description, the embodiments of the present disclosure only illustrate a structure of a buck switching power supply serving as the switching power supply.

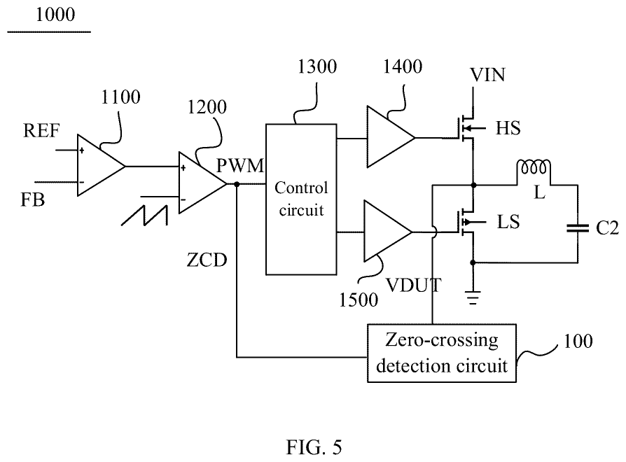

FIG. 5 is a schematic structural diagram of a switching power supply 1000 according to some embodiments of the present disclosure. As illustrated in FIG. 5, the switching power supply 1000 may include an operational amplifier circuit 1100, a pulse width modulation comparator circuit 1200, a control circuit 1300, a first driver circuit 1400, a second driver circuit 1500, a high-side power transistor HS, a low-side power transistor LS, a freewheeling inductor L, a second capacitor C2, and a zero-crossing detection circuit 100.

A first input terminal of the operational amplifier circuit 1100 is configured to receive a reference signal REF, a second input terminal of the operational amplifier circuit 1100 is configured to receive a feedback signal FB, an output terminal of the operational amplifier circuit 1100 is electrically connected to a first input terminal of the pulse width modulation comparator circuit 1200, a second terminal of the pulse width modulation comparator circuit 1200 is configured to receive a triangle wave signal, an output terminal of the pulse width modulation comparator circuit 1200 and an output terminal of the zero-crossing detection circuit 100 are both electrically connected to an input terminal of the control circuit 1300, an output terminal of the control circuit 1300 is electrically connected to an input terminal of the first driver circuit 1400 and an input terminal of the second driver circuit 1500, an output terminal of the first driver circuit 1400 is electrically connected to a control terminal of the high-side power transistor HS, an output terminal of the second driver circuit 1500 is electrically connected to a control terminal of the low-side power transistor LS, a first terminal of the high-side power transistor HS is configured to receive a power supply voltage VIN, a second terminal of the high-side power transistor HS is electrically connected to a first terminal of the low-side power transistor LS, an input terminal of the zero-crossing detection circuit 100 and a first terminal of the freewheeling inductor L are both electrically connected between the second terminal of the high-side power transistor HS and the first terminal of the low-side power transistor LS, a second terminal of the freewheeling inductor L is electrically connected to a first terminal of the second capacitor C2, and a second terminal of the low-side power transistor LS and a second terminal of the second capacitor C2 are both grounded.

For example, the high-side power transistor HS is an N-type metal-oxide-semiconductor field-effect transistor (NMOSFET), and the low-side power transistor LS is a P-type metal-oxide-semiconductor field-effect transistor (PMOSFET).

The control terminal of the high-side power transistor HS is a gate electrode G, the first terminal of the high-side power transistor HS is a drain electrode D, and the second terminal of the high-side power transistor HS is a source electrode S.

The control terminal of the low-side power transistor LS is a gate electrode G, the first terminal of the low-side power transistor LS is a source electrode S, and the second terminal of the low-side power transistor LS is a drain electrode D.

The high-side power transistor HS and the low-side power transistor LS are both power transistors.

The operational amplifier circuit 1100 is configured to acquire an output signal of the operational amplifier circuit 1100 based on the reference signal REF and the feedback signal FB, and transmit the output signal of the operational amplifier circuit 1100 to the pulse width modulation comparator circuit 1200.

As such, the pulse width modulation comparator circuit 1200 is configured to transmit a pulse width modulation signal PWM to the control circuit 1300 based on the output signal of the operational amplifier circuit 1100 and the triangle wave signal.

In the meantime, the zero-crossing detection circuit 100 is configured to acquire a voltage VDUT to be measured from the high-side power transistor HS or the low-side power transistor LS. In this way, the zero-crossing detection circuit 100 is configured to transmit a turn-off control signal ZCD to the control circuit 1300 based on a precision reference voltage V_REF_ZCD and the voltage VDUT to be measured. The voltage VDUT to be measured includes a difference between a voltage at the second terminal of the high-side power transistor HS and a zero voltage or a difference between a voltage at the first terminal of the low-side power transistor LS and the zero voltage.

In the case that the first driver circuit 1400 is configured to control turn-on or turn-off of the high-side power transistor HS based on a turn-on or turn-off control signal, the voltage VDUT to be measured is a difference between the voltage at the second terminal of the high-side power transistor HS and the zero voltage. In the case that the second driver circuit 1500 is configured to control turn-on or turn-off of the low-side power transistor LS based on a turn-on or turn-off control signal, the voltage VDUT to be measured is a difference between the voltage at the first terminal of the low-side power transistor LS and the zero voltage.

As such, the control circuit 1300 is configured to transmit a turn-on or turn off control signal to the first driver circuit 1400 and the second driver circuit 1500 based on the pulse width modulation signal PWM and the turn-off control signal ZCD.

Hence, the first driver circuit 1400 is configured to control turn-on or turn-off of the high-side power transistor HS based on the turn-on or turn-off control signal, such that a turn-off timing of the high-side power transistor HS is more accurate. The second driver circuit 1500 is configured to control turn-on or turn-off of the low-side power transistor LS based on the turn-on or turn-off control signal, such that a turn-off timing of the low-side power transistor LS is more accurate.

In this way, the switching power supply 1000 has a higher light-load efficiency.

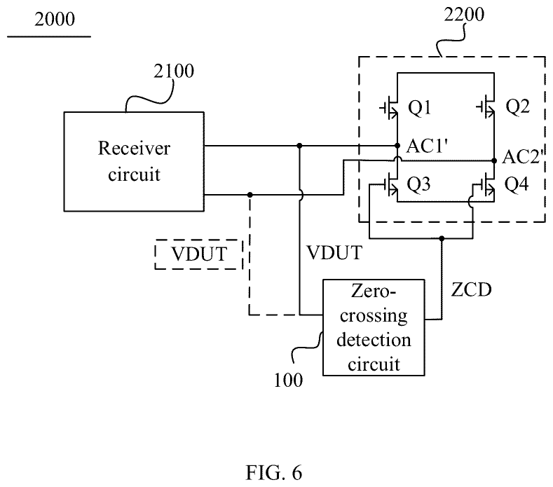

FIG. 6 is a schematic structural diagram of a wireless charging receiver 2000 according to some embodiments of the present disclosure. As illustrated in FIG. 6, the wireless charging receiver 2000 may include a receiver circuit 2100, a rectifier circuit 2200, and a zero-crossing detection circuit 100.

A first output terminal of the receiver circuit 2100 is electrically connected to a first input terminal of the rectifier circuit 2200, a second output terminal of the receiver circuit 2100 is electrically connected to a second input terminal of the rectifier circuit 2200, an input terminal of the zero-crossing detection circuit 100 is electrically connected between the first output terminal of the receiver circuit 2100 and the first input terminal of the rectifier circuit 2200 or between the second output terminal of the receiver circuit 2100 and the second input terminal of the rectifier circuit 2200, and an output terminal of the zero-crossing detection circuit 100 is electrically connected to a control terminal of the rectifier circuit 2200.

The receiver circuit 2100 is configured to receive an alternating current (AC) voltage via the receive coil, and transmit the AC voltage to the rectifier circuit 2200. As such, the rectifier circuit 2200 is configured to convert the AC voltage to a direct current (DC) voltage. In the case that a current at the first input terminal or the second input terminal of the rectifier circuit 2200 is less than a predetermined current, the zero-crossing detection circuit 100 is configured to acquire the voltage VDUT to be measured from the rectifier circuit 2200. In this way, some of the power transistors in the rectifier circuit 2200 are turned off based on the precision reference voltage V_REF_ZCD and the voltage VDUT to be measured. Hence, the receive coil in the receiver circuit 2100 is prevented from current backflow, and thus the stability of the rectifier circuit 2200 is improved. In this way, the wireless charging receiver 2000 has higher stability and efficiency.

The voltage VDUC to be measured includes a difference between the zero voltage and a voltage at the first input terminal of the rectifier circuit 2200, or a difference between the zero voltage and a voltage at the second input terminal of the rectifier circuit 2200. In the case that the current at the first input terminal of the rectifier circuit 2200 is less than the predetermined current, the voltage VDUT to be measured is the difference between the zero voltage and the voltage at the first input terminal of the rectifier circuit 2200. As such, the zero-crossing detection circuit 100 acquires a turn-off control signal ZCD based on the voltage at the first input terminal of the rectifier circuit 2200 and the precision reference voltage V_REF_ZCD, and turns off a second power transistor Q2 and a third power transistor Q3 in the rectifier circuit 2200 based on the turn-off control signal ZCD.

In the case that the current at the second input terminal of the rectifier circuit 2200 is less than the predetermined current, the voltage VDUT to be measured is the difference between the zero voltage and the voltage at the second input terminal of the rectifier circuit 2200. As such, the zero-crossing detection circuit 100 acquires a turn-off control signal ZCD based on the voltage at the second input terminal of the rectifier circuit 2200 and the precision reference voltage V_REF_ZCD, and turns off a first power transistor Q1 and a fourth power transistor Q4 in the rectifier circuit 2200 based on the turn-off control signal ZCD.

For ease of understanding, embodiments hereinafter are described by an example where the zero-crossing detection circuit 100 is applied to a wireless charging receiver 2000.

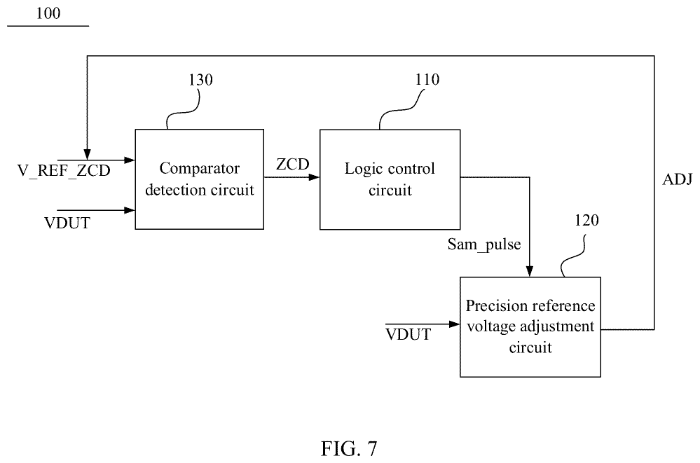

FIG. 7 illustrates a schematic structural diagram of the zero-crossing detection circuit 100 in FIG. 5 and FIG. 6. As illustrated in FIG. 7, the zero-crossing detection circuit 100 may include a comparator detection circuit 130, a precision reference voltage adjustment circuit 120, and a logic control circuit 110.

A first input terminal of the comparator detection circuit 130 is configured to receive a precision reference voltage V_REF_ZCD, a second input terminal of the comparator detection circuit 130 is configured receive a voltage VDUT to be measured in response to turn-on of the power transistor, an input terminal of the precision reference voltage adjustment circuit 120 is configured to receive a voltage VDUT to be measured upon completion of turn-off of the power transistors, an output terminal of the comparator detection circuit 130 is electrically connected to an input terminal of the logic control circuit 110, an output terminal of the logic control circuit 110 is electrically connected to a control terminal of the precision reference voltage adjustment circuit 120, and an output terminal of the precision reference voltage adjustment circuit 120 is electrically connected to the first input terminal of the comparator detection circuit 130.

The comparator detection circuit 130, the precision reference voltage adjustment circuit 120, and the logic control circuit 110 may be separately arranged, or may be integrally arranged.

The output terminal of the comparator detection circuit 130 is the output terminal of the zero-crossing detection circuit 100.

In the case that the zero-crossing detection circuit 100 is applied to a switching power supply 1000, the output terminal of the comparator detection circuit 130 is electrically connected to the input terminal of the control circuit 1300, and the second input terminal of the comparator detection circuit 130 and the input terminal of the precision reference voltage adjustment circuit 120 are both electrically connected between the second terminal of the high-side power transistor HS and the first terminal of the low-side power transistor LS. In the case that the zero-crossing detection circuit 100 controls the high-side power transistor HS to be turned off, the controlled power transistor is the high-side power transistor HS. In the case that the zero-crossing detection circuit 100 controls the low-side power transistor LS to be turned off, the controlled power transistor is the low-side power transistor LS.

In the case that the zero-crossing detection circuit 100 is applied to a wireless charging receiver 2000, the second input terminal of the comparator detection circuit 130 and the input terminal of the precision reference voltage adjustment circuit 120 are both electrically connected between the first output terminal of the receiver circuit 2100 and the first input terminal of the rectifier circuit 2200 or between the second output terminal of the receiver circuit 2100 and the second input terminal of the rectifier circuit 2200, and the output terminal of the comparator detection circuit 130 is electrically connected to a control terminal of the rectifier circuit 2200. In the case that the zero-crossing detection circuit 100 controls the second power transistor Q2 and the third power transistor Q3 in the rectifier circuit 2200 to be turned off, the controlled power transistors are the second power transistor Q2 and the third power transistor Q3. In the case that the zero-crossing detection circuit 100 controls the first power transistor Q1 and the fourth power transistor Q4 in the rectifier circuit 2200 to be turned off, the controlled power transistors are the first power transistor Q1 and the fourth power transistor Q4.

The comparator detection circuit 130 is configured to acquire, with respect to two adjacent clock cycles, a turn-off control signal within a preceding clock cycle based on a precision reference voltage V_REF_ZCD within the preceding clock cycle and the voltage VDUT to be measured in response to turn-on of the power transistor. Furthermore, the comparator detection circuit 130 is configured to transmit the turn-off control signal ZCD within the preceding clock cycle to the logic control circuit 110.

The turn-off control signal ZCD may indicate a magnitude relationship between the voltage VDUT to be measured and the precision reference voltage V_REF_ZCD. For example, in the case that the voltage VDUT to be measured is less than the precision reference voltage V_REF_ZCD, the turn-off control signal ZCD is at a low level. For example, in the case that the voltage VDUT to be measured is greater than the precision reference voltage V_REF_ZCD, the turn-off control signal ZCD is at a high level such that some of the power transistors in the rectifier circuit 2200 are turned off. For example, in the case that the voltage VDUT to be measured is greater than the precision reference voltage V_REF_ZCD, the turn-off control signal ZCD is at a low level. For example, in the case that the voltage VDUT to be measured is less than the precision reference voltage V_REF_ZCD, the turn-off control signal ZCD is at a high level.

In the case that some of the power transistors in the rectifier circuit 2200 are N-type transistors, the turn-off control signal ZCD is at a high level such that some of the power transistors in the rectifier circuit 2200 are turned off. In the case that the zero-crossing detection circuit 100 controls the first power transistor Q1 and the fourth power transistor Q4, some the power transistors are the first power transistor Q1 and the fourth power transistor Q4. In the case that the zero-crossing detection circuit 100 controls the second power transistor Q2 and the third power transistor Q3 to be turned off, some of the power transistors are the second power transistor Q2 and the third power transistor Q3.

Thus, in the case that the turn-off control signal ZCD within the preceding clock cycle transitions from a low level to a high level, the logic control circuit 110 is configured to take a rising trigger edge of the turn-off control signal ZCD within the preceding clock cycle as an enable signal Sam_pulse within the preceding clock cycle based on the turn-off control signal ZCD within the preceding clock cycle. In this way, the logic control circuit 110 acquires the enable signal Sam_pulse within the preceding clock cycle. Furthermore, the logic control circuit 110 is configured to transmit the enable signal Sam_pulse within the preceding clock cycle to the precision reference voltage adjustment circuit 120.

For example, in the case that the enable signal Sam_pulse within the preceding clock cycle is at a high level, the precision reference voltage adjustment circuit 120 is in an operating state. For example, in the case that the enable signal Sam_pulse within the preceding clock cycle is at a low level, the precision reference voltage adjustment circuit 120 is in a non-operating state.

In this way, in the case that the enable signal Sam_pulse within the preceding clock cycle is at a high level, the precision reference voltage adjustment circuit 120 is configured to, under an effect of the enable signal Sam_pulse within the preceding clock cycle, acquire an adjustment signal ADJ within a subsequent clock cycle based on changes of the voltage VDUT to be measured upon completion of turn-off of the power transistors, and transmit the adjustment signal within the subsequent clock cycle to the comparator detection circuit 130.

The adjustment signal ADJ within the subsequent clock cycle is used for adjusting a value of the precision reference voltage V_REF_ZCD. In the case that the voltage VDUT upon completion of turn-off of the power transistors increases, the adjustment signal ADJ within the subsequent clock cycle is capable of increasing the value of the precision reference voltage V_REF_ZCD. In the case that the voltage VDUT upon completion of turn-off of the power transistors decreases, the adjustment signal ADJ within the subsequent clock cycle is capable of decreasing the value of the precision reference voltage V_REF_ZCD.

The adjustment signal ADJ is a digital signal, that is, a sequence of binary numbers. The more the digits of the binary sequence, the more accurate the value of the precision reference voltage V_REF_ZCD adjusted by the adjustment signal ADJ within the subsequent clock cycle. In the case that a code value corresponding to the adjustment signal ADJ increases within the subsequent clock cycle, the value of the precision reference voltage V_REF_ZCD within the subsequent clock cycle increases. In the case that a code value corresponding to the adjustment signal ADJ within the subsequent clock cycle decreases, the value of the precision reference voltage V_REF_ZCD within the subsequent clock cycle decreases. For example, in the case that the adjustment signal ADJ within the subsequent clock cycle changes from 100000 to 100001, the value of the precision reference voltage V_REF_ZCD within the subsequent clock cycle changes from 0 mV to 2.5 m V. For example, in the case that the adjustment signal ADJ within the subsequent clock cycle changes from 100001 to 100000, the value of the precision reference voltage V_REF_ZCD within the subsequent clock cycle changes from 2.5 mV to 0 mV.

Within the preceding clock cycle, the fact that the voltage VDUT to be measured upon completion of turn-off of the power transistors is greater than the reference voltage VREF means that after some the power transistors in the rectifier circuit 2200 are controlled to be turned off by the turn-off control signal ZCD within the preceding clock cycle, turn-on of parasitic diodes in some the power transistors is obvious. This indicates that the turn-off control signal ZCD within the preceding clock cycle prematurely controls the some of the power transistors in the rectifier circuit 2200 to be turned off. That is, the turn-off timings of some of the power transistors are advanced (ahead of the turn-off timing as scheduled), that is, it is not accurate. In this way, within the subsequent clock cycle, the precision reference voltage adjustment circuit 120 is capable of increasing the precision reference voltage V_REF_ZCD within the subsequent clock cycle based on the adjustment signal ADJ within the subsequent clock cycle, that is, raising the reference point of the comparator detection circuit 130 within the subsequent clock cycle. Hence, the comparator detection circuit 130 is capable of acquiring the turn-off control signal ZCD within the subsequent clock cycle based on the adjusted precision reference voltage V_REF_ZCD and the voltage VDUT to be measured, such that the precision of the turn-off control signal ZCD within the subsequent clock cycle is improved. As such, within the subsequent clock cycle, the turn-off timings of some of the power transistors are delayed (later than the turn-off timings as scheduled).

Within the preceding clock cycle, the fact that the voltage VDUT to be measured upon completion of turn-off of the power transistors is less than the reference voltage VREF means that after some the power transistors in the rectifier circuit 2200 are controlled to be turned off by the turn-off control signal ZCD within the preceding clock cycle, turn-on of parasitic diodes in some the power transistors is not obvious. This indicates that the turn-off control signal ZCD within the preceding clock cycle controls the some of the power transistors in the rectifier circuit 2200 to be turned off too late. That is, the turn-off timings of some of the power transistors are delayed (later than the turn-off timings as scheduled). In this way, within the subsequent clock cycle, the precision reference voltage adjustment circuit 120 is capable of decreasing the precision reference voltage V_REF_ZCD within the subsequent clock cycle based on the adjustment signal ADJ within the subsequent clock cycle, that is, lowering the reference point of the comparator detection circuit 130 within the subsequent clock cycle. Hence, the comparator detection circuit 130 is capable of acquiring the turn-off control signal ZCD within the subsequent clock cycle based on the adjusted precision reference voltage V_REF_ZCD and the voltage VDUT to be measured, such that the precision of the turn-off control signal ZCD within the subsequent clock cycle is improved. As such, within the subsequent clock cycle, the turn-off timings of some of the power transistors are advanced (ahead of the turn-off timings as scheduled).

With respect to the switching power supply 1000, one clock cycle refers to a process in which in the case that the current of the freewheeling inductor L decreases to 0, the zero-crossing detection circuit 100 transmits the turn-off control signal ZCD to the control circuit 1300 such that the high-side power transistor HS or the low-side power transistor LS is turned off to prevent backflow of the current of the freewheeling inductor L. With respect to the wireless charging receiver 2000, one clock cycle refers to a process in which upon completion of charging of the wireless charging receiver 2000, the zero-crossing detection circuit 100 turns off some of the power transistors in the rectifier circuit 2200 based on the turn-off control signal ZCD to prevent backflow of the current of the receive coil in the receiver circuit 2100.

In this way, through several clock cycles, the turn-off timings of some of the power transistors are adjusted to be closest to the precision turn-off timing, such that the detection precision of the zero-crossing detection circuit 100 is improved.

In the zero-crossing detection circuit according to the present disclosure, the comparator detection circuit is capable of, with respect to two adjacent clock cycles, acquiring a turn-off control signal within a preceding clock cycle based on a precision reference voltage within the preceding clock cycle and the voltage to be measured in response to turn-on of the power transistor, and outputting the turn-off control signal within the preceding clock cycle to the logic control circuit, such that the logic control circuit acquire the enable signal within the preceding clock cycle based on the turn-off control signal within the preceding clock cycle. In this way, the logic control circuit is capable of transmitting the enable signal within the preceding clock cycle to the precision reference voltage adjustment circuit, such that the precision reference voltage adjustment circuit acquires, under an effect of the enable signal within the preceding clock cycle, an adjustment signal within a subsequent clock cycle based on changes of the voltage to be measured upon completion of turn-off of the power transistors. Hence, the precision reference voltage adjustment circuit is capable of transmitting the adjustment signal within the subsequent clock cycle to the comparator detection circuit, such that the comparator detection circuit changes the precision reference voltage within the preceding clock cycle based on the adjustment signal within the subsequent clock cycle and acquires the precision reference voltage within the subsequent clock cycle. As such, a reference point of the comparator detection circuit within the subsequent clock is adjusted, such that the accuracy of the turn-off control signal within the subsequent clock cycle is improved. In this way, the turn-off timings of the power transistors are adjusted to be closest to the precision turn-off timing.

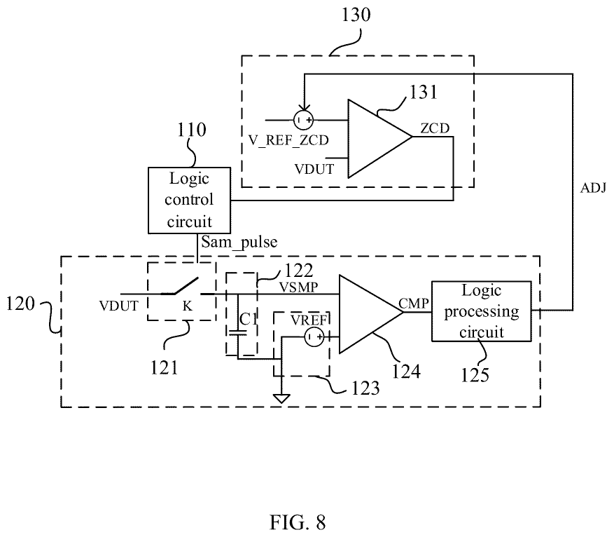

Based on the description of the above embodiment, exemplarily, one possible implementation of the precision reference voltage adjustment circuit 120 is described hereinafter. FIG. 8 illustrates a schematic structural diagram of a zero-crossing detection circuit according to some embodiments of the present disclosure. As illustrated in FIG. 8, the precision reference voltage adjustment circuit 120 may include a switch assembly 121, a voltage sampling circuit 122, a reference circuit 123, a comparator circuit 124, and a logic processing circuit 125.

A first terminal of the switch assembly 121 is configured to receive the voltage VDUT to be measured upon completion of the power transistors, a control terminal of the switch assembly 121 is electrically connected to the output terminal of the logic control circuit 110, a second terminal of the switch assembly 121 is electrically connected to a first input terminal of the comparator circuit 124, a first terminal of the voltage sampling circuit 122 is electrically connected between the second terminal of the switch assembly 121 and the first input terminal of the comparator circuit 124, a second terminal of the voltage sampling circuit 122 and a first terminal of the reference circuit 123 are both grounded, a second terminal of the reference circuit 123 is electrically connected to a second input terminal of the comparator circuit 124, an output terminal of the comparator circuit 124 is electrically connected to an input terminal of the logic processing circuit 125, and an output terminal of the logic processing circuit 125 is electrically connected to the first input terminal of the comparator detection circuit 130.

The switch assembly 121 may include one switch transistor K or a switch group of a plurality of switch transistors K, which is not limited in an embodiment of the present disclosure. For ease of description, the following embodiments use the case where the switch assembly 121 includes one switch transistor K as an example for illustration.

The logic control circuit 110 is configured to transmit the enable signal Sam_pulse within the preceding clock cycle to the switch assembly 121. As such, under the effect of the enable signal Sam_pulse within the preceding clock cycle, the switch assembly 121 is turned on. In this way, in the case that the switch assembly 121 is turned on, the voltage sampling circuit 122 samples the voltage VDUT to be measured upon completion of turn-off of the power transistors to acquire a sampled voltage VSMP. In addition, the voltage sampling circuit 122 transmits the sampled voltage VSMP to the comparator circuit 124. A value of the sampled voltage VSMP may be equal to the value of the voltage VDUT to be measured, and the voltage of the sampled voltage VSMP may also be proportional to the value of the voltage VDUT to be measured.

In the meantime, the reference circuit 123 transmits the reference voltage VREF to the comparator circuit 124. For example, the reference circuit 123 is a constant-voltage power supply.

The reference voltage is used for determining whether the power transistor is turned off on time in response to the turn-off control signal within the preceding clock cycle. In the case that the voltage VDUT to be measured upon completion of turn-off of the power transistors is greater than the reference voltage VREF, that is, the sampled voltage VSMP is greater than the reference voltage VREF, the turn-off control signal within the preceding clock cycle prematurely turns off the power transistors. In the case that the voltage VDUT to be measured upon completion of turn-off of the power transistors is less than the reference voltage VREF, that is, the sampled voltage VSMP is greater than the reference voltage VREF, the turn-off control signal within the preceding clock cycle turns off the power transistors too late.

As such, the comparator circuit 124 acquires a digital signal CMP based on the sampled voltage VSMP and the reference signal VREF. In addition, the comparator circuit 124 transmits the digital signal CMP to the logic processing circuit 125.

For example, in the case that the sampled voltage VSMP is greater than the reference signal VREF, the digital signal CMP is at a high level. For example, in the case that the sampled voltage VSMP is less than the reference signal VREF, the digital signal CMP is at a low level. For example, in the case that the sampled voltage VSMP is less than the reference signal VREF, the digital signal CMP is at a high level. For example, in the case that the sampled voltage VSMP is greater than the reference signal VREF, the digital signal CMP is at a low level.

Hence, the logic processing circuit 125 is configured to generate the adjustment signal ADJ within the subsequent clock cycle based on the digital signal CMP.

In the case that the digital signal CMP is at a high level, the code value corresponding to the adjustment signal ADJ within the subsequent clock cycle increases by 1. In the case that the digital signal CMP is at low level, the code value corresponding to the adjustment signal ADJ within the subsequent clock cycle decreases by 1.

In some examples, when the digital signal CMP indicates that the voltage VDUT to be measured upon completion of turn-off of the power transistors is greater than the reference voltage VREF, turn-off timing of some of the power transistors is advanced. In this way, the logic processing circuit 125 increases the precision reference voltage V_REF_ZCD within the subsequent clock cycle based on the adjustment signal ADJ within the preceding clock cycle, that is, raises the reference point of the comparator detection circuit 130.

Alternatively, when the digital signal CMP indicates that the voltage VDUT to be measured upon completion of turn-off of the power transistors is less than the reference voltage VREF, turn-off timing of some of the power transistors is delayed. In this way, the logic processing circuit 125 decreases the precision reference voltage V_REF_ZCD within the subsequent clock cycle based on the adjustment signal ADJ within the preceding clock cycle, that is, lowers the reference point of the comparator detection circuit 130.

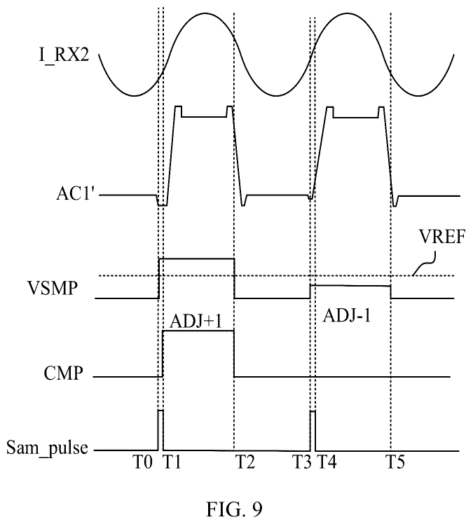

FIG. 9 illustrates a schematic diagram of an operating waveform of the zero-crossing detection circuit in FIG. 6 to FIG. 8. Hereinafter, the operating principles of the zero-crossing detection circuit 100 are described in detail. T0-T2 is a preceding clock cycle, and T3-T5 is a subsequent clock cycle.

Within T0-T1, under the effect of the enable signal Sam_pulse within the preceding clock cycle, the switch assembly 121 is turned on. In this way, the voltage sampling circuit 122 samples the voltage VDUT to be measured upon completion of turn-off of the power transistors to acquire a sampled voltage VSMP. In addition, the voltage sampling circuit 122 transmits the sampled voltage VSMP to the comparator circuit 124.

Within T1-T2, since the sampled voltage VSMP in the comparator circuit 124 is greater than the reference voltage VREF, the digital signal CMP output by the comparator circuit 124 is at a high level. As such, a code value of an adjustment signal ADJ within the subsequent clock cycle output by the logic processing circuit 125 increases 1. That is, a code value of the adjustment signal ADJ within the subsequent clock cycle output by the precision reference voltage adjustment circuit 120 increases 1, such that the precision reference voltage V_REF_ZCD within the preceding clock cycle of the comparator detection circuit 130 increases, and the precision reference voltage V_REF_ZCD within the subsequent clock cycle is acquired.

Within T3-T4, under the effect of the enable signal Sam_pulse within the preceding clock cycle, the switch assembly 121 is turned on. In this way, the voltage sampling circuit 122 is capable of sampling the voltage VDUT to be measured upon completion of turn-off of the power transistors to acquire a sampled voltage VSMP. In addition, the voltage sampling circuit 122 transmits the sampled voltage VSMP to the comparator circuit 124.

Within T4-T5, since the sampled voltage VSMP is less than the reference voltage VREF, the digital signal CMP output by the comparator circuit 124 is at a low level. As such, a code value of an adjustment signal ADJ within the subsequent clock cycle output by the logic processing circuit 125 decreases 1. That is, a code value of the adjustment signal ADJ within the subsequent clock cycle output by the precision reference voltage adjustment circuit 120 decreases 1, such that the precision reference voltage V_REF_ZCD within the preceding clock cycle of the comparator detection circuit 130 decreases, and the precision reference voltage V_REF_ZCD within the subsequent clock cycle is acquired.

In summary, under the effect of the enable signal within the preceding clock cycle, the switch assembly is turned on, such that the voltage sampling circuit acquires the sampled voltage. In this way, the voltage sampling circuit transmits the sampled voltage to the comparator circuit. In the meantime, the reference circuit transmits the reference voltage to the comparator circuit. Hence, the comparator circuit acquires the digital signal based on the sampled voltage and the reference voltage, such that the logic processing circuit generates the adjustment signal within the subsequent clock cycle based on the digital signal. In this way, the comparator detection circuit changes the precision reference voltage within the preceding clock cycle based on the adjustment signal within the subsequent clock cycle.

Based on the description of the above embodiments, exemplarily, one possible implementation of the comparator circuit 124 is described hereinafter. As illustrated in FIG. 8, the comparison circuit 124 may include a comparator.

A first input terminal of the comparator is electrically connected to an output terminal of the voltage sampling circuit 122, a second input terminal of the comparator is electrically connected to the second terminal of the reference circuit 123, and an output terminal of the comparator is electrically connected to the input terminal of the logic processing circuit 125.

The first input terminal of the comparator is a non-inverting input terminal, and the second input terminal of the comparator is an inverting input terminal.

Based on the description of the above embodiment, exemplarily, one possible implementation of the voltage sampling circuit 122 is described hereinafter. As illustrated in FIG. 8, the voltage sampling circuit 122 may include a first capacitor C1.

In some embodiments, a first terminal of the first capacitor C1 is electrically connected between the second terminal of the switch assembly 121 and the first input terminal of the comparator circuit 124, and a second terminal of the first capacitor C1 is grounded.

In the case that the switch assembly 121 is turned on, since the first capacitor C1 has the function of storing electrical energy, the first capacitor C1 samples the voltage VDUT to be measured to acquire the sampled voltage VSMP.

In summary, the first capacitor samples the voltage to be measured and acquires the sampled voltage, such that the voltage sampling circuit is capable of transmitting the sampled voltage to the comparator circuit.

Based on the description of the above embodiments, exemplarily, one possible implementation of the comparator detection circuit 130 is described hereinafter. As illustrated in FIG. 8, the comparison detection circuit 130 may include a zero-crossing detection comparator.

A first input terminal of the zero-crossing detection comparator is configured to receive the precision reference voltage V_REF_ZCD, a second input terminal of the zero-crossing detection comparator is configured to receive the voltage VDUT to be measured in response to turn-on of the power transistor, and an output terminal of the zero-crossing detection comparator is electrically connected to the input terminal of the logic control circuit 110.

The first input terminal of the zero-crossing detection comparator is a non-inverting input terminal, and the second input terminal of the zero-crossing detection comparator is an inverting input terminal.

It should be finally noted that the above embodiments are used only for illustrating the present disclosure, but are not intended to limit the protection scope of the present disclosure. Various modifications and replacements readily derived by those skilled in the art within technical disclosure of the present disclosure shall fall within the protection scope of the present disclosure. Therefore, the protection scope of the present disclosure is subject to the appended claims.

What is claimed is:

1. A zero-crossing detection circuit, comprising: a comparator detection circuit, a precision reference voltage adjustment circuit, and a logic control circuit; wherein
a first input terminal of the comparator detection circuit is configured to receive a precision reference voltage, a second input terminal of the comparator detection circuit is configured to receive a voltage to be measured in response to turn-on of a power transistor of a wireless charging receiver or a switching power supply, an input terminal of the precision reference voltage adjustment circuit is configured to receive a voltage to be measured upon completion of turn-off of the power transistor, an output terminal of the comparator detection circuit is electrically connected to an input terminal of the logic control circuit, an output terminal of the logic control circuit is electrically connected to a control terminal of the precision reference voltage adjustment circuit, and an output terminal of the precision reference voltage adjustment circuit is electrically connected to the first input terminal of the comparator detection circuit;
the comparator detection circuit is configured to, with respect to two adjacent clock cycles, acquire a turn-off control signal within a preceding clock cycle of the two adjacent clock cycles based on a precision reference voltage within the preceding clock cycle and the voltage to be measured in response to turn-on of the power transistor, and transmit the turn-off control signal within the preceding clock cycle to the logic control circuit, wherein the turn-off control signal within the preceding clock cycle is used for controlling the power transistor to be turned off;
the logic control circuit is configured to acquire an enable signal within the preceding clock cycle based on the turn-off control signal within the preceding clock cycle, and transmit the enable signal within the preceding clock cycle to the precision reference voltage adjustment circuit;
the precision reference voltage adjustment circuit is configured to, under an effect of the enable signal within the preceding clock cycle, acquire an adjustment signal within a subsequent clock cycle of the two adjacent clock cycles based on changes of the voltage to be measured upon completion of turn-off of the power transistor, and transmit the adjustment signal within the subsequent clock cycle to the comparator detection circuit; and
the comparator detection circuit is configured to adjust the precision reference voltage within the preceding clock cycle based on the adjustment signal within the subsequent clock cycle to acquire a precision reference voltage within the subsequent clock cycle, and acquire a turn-off control signal within the subsequent clock cycle based on the precision reference voltage within the subsequent clock cycle and the voltage to be measured in response to turn-on of the power transistor, wherein the turn-off control signal within the subsequent clock cycle is used for controlling the power transistor to be turned off.

2. The zero-crossing detection circuit according to claim 1, wherein the precision reference voltage adjustment circuit comprises a switch assembly, a voltage sampling circuit, a reference circuit, a comparator circuit, and a logic processing circuit; wherein
a first terminal of the switch assembly is configured to receive the voltage to be measured upon completion of the power transistor, a control terminal of the switch assembly is electrically connected to the output terminal of the logic control circuit, a second terminal of the switch assembly is electrically connected to a first input terminal of the comparator circuit, a first terminal of the voltage sampling circuit is electrically connected between the second terminal of the switch assembly and the first input terminal of the comparator circuit, a second terminal of the voltage sampling circuit and a first terminal of the reference circuit are both grounded, a second terminal of the reference circuit is electrically connected to a second input terminal of the comparator circuit, an output terminal of the comparator circuit is electrically connected to an input terminal of the logic processing circuit, and an output terminal of the logic processing circuit is electrically connected to the first input terminal of the comparator detection circuit;
the logic control circuit is configured to transmit the enable signal within the preceding clock cycle to the switch assembly, wherein the switch assembly is turned on under the effect of the enable signal within the preceding clock cycle;
the voltage sampling circuit is configured to, upon turn-on of the switch assembly, sample the voltage to be measured upon completion of turn-off of the power transistor to acquire a sampled voltage, transmit the sampled voltage to the comparator circuit, wherein the sampled voltage is related to the voltage to be measured upon completion of turn-off of the power transistor;
the reference circuit is configured to transmit a reference voltage to the comparator circuit, wherein the reference voltage is used for determining whether the power transistor is turned off on time in response to the turn-off control signal within the preceding clock cycle;
the comparator circuit is configured to acquire a digital signal based on the sampled voltage and the reference voltage, and transmit the digital signal to the logic processing circuit; and
the logic processing circuit is configured to generate the adjustment signal within the subsequent clock cycle based on the digital signal.

3. The zero-crossing detection circuit according to claim 2, wherein the logic control circuit is configured to increase the precision reference voltage within the preceding clock cycle using the adjustment signal within the subsequent clock cycle in a case that the digital signal indicates that the voltage to be measured upon completion of turn-off of the power transistor is greater than the reference voltage; or
the logic control circuit is configured to decrease the precision reference voltage within the preceding clock cycle using the adjustment signal within the subsequent clock cycle in a case that the digital signal indicates that the voltage to be measured upon completion of turn-off of the power transistor is less than the reference voltage.

4. The zero-crossing detection circuit according to claim 2, wherein the comparator circuit comprises a comparator;
wherein a first input terminal of the comparator is electrically connected to an output terminal of the voltage sampling circuit, a second input terminal of the comparator is electrically connected to the second terminal of the reference circuit, and an output terminal of the comparator is electrically connected to the input terminal of the logic processing circuit.

5. The zero-crossing detection circuit according to claim 2, wherein the voltage sampling circuit comprises a first capacitor; wherein a first terminal of the first capacitor is electrically connected between the second terminal of the switch assembly and the first input terminal of the comparator circuit, and a second terminal of the first capacitor is grounded.

6. The zero-crossing detection circuit according to claim 1, wherein the comparator detection circuit comprises a zero-crossing detection comparator; wherein a first input terminal of the zero-crossing detection comparator is configured to receive the precision reference voltage, a second input terminal of the zero-crossing detection comparator is configured to receive the voltage to be measured in response to turn-on of the power transistor, and an output terminal of the zero-crossing detection comparator is electrically connected to the input terminal of the logic control circuit.

7. A wireless charging receiver, comprising: a receiver circuit, a rectifier circuit, and a zero-crossing detection circuit; wherein the zero-crossing detection circuit comprises: a comparator detection circuit, a precision reference voltage adjustment circuit, and a logic control circuit; wherein
a first input terminal of the comparator detection circuit is configured to receive a precision reference voltage, a second input terminal of the comparator detection circuit is configured to receive a voltage to be measured in response to turn-on of a power transistor of a wireless charging receiver or a switching power supply, an input terminal of the precision reference voltage adjustment circuit is configured to receive a voltage to be measured upon completion of turn-off of the power transistor, an output terminal of the comparator detection circuit is electrically connected to an input terminal of the logic control circuit, an output terminal of the logic control circuit is electrically connected to a control terminal of the precision reference voltage adjustment circuit, and an output terminal of the precision reference voltage adjustment circuit is electrically connected to the first input terminal of the comparator detection circuit;
the comparator detection circuit is configured to, with respect to two adjacent clock cycles, acquire a turn-off control signal within a preceding clock cycle of the two adjacent clock cycles based on a precision reference voltage within the preceding clock cycle and the voltage to be measured in response to turn-on of the power transistor, and transmit the turn-off control signal within the preceding clock cycle to the logic control circuit, wherein the turn-off control signal within the preceding clock cycle is used for controlling the power transistor to be turned off;
the logic control circuit is configured to acquire an enable signal within the preceding clock cycle based on the turn-off control signal within the preceding clock cycle, and transmit the enable signal within the preceding clock cycle to the precision reference voltage adjustment circuit;
the precision reference voltage adjustment circuit is configured to, under an effect of the enable signal within the preceding clock cycle, acquire an adjustment signal within a subsequent clock cycle of the two adjacent clock cycles based on changes of the voltage to be measured upon completion of turn-off of the power transistor, and transmit the adjustment signal within the subsequent clock cycle to the comparator detection circuit;
the comparator detection circuit is configured to adjust the precision reference voltage within the preceding clock cycle based on the adjustment signal within the subsequent clock cycle to acquire a precision reference voltage within the subsequent clock cycle, and acquire a turn-off control signal within the subsequent clock cycle based on the precision reference voltage within the subsequent clock cycle and the voltage to be measured in response to turn-on of the power transistor, wherein the turn-off control signal within the subsequent clock cycle is used for controlling the power transistor to be turned off;
a first output terminal of the receiver circuit is electrically connected to a first input terminal of the rectifier circuit, a second output terminal of the receiver circuit is electrically connected to a second input terminal of the rectifier circuit, the second input terminal of the comparator detection circuit and the input terminal of the precision reference adjustment circuit are both electrically connected between the first output terminal of the receiver circuit and the first input terminal of the rectifier circuit or between the second output terminal of the receiver circuit and the second input terminal of the rectifier circuit, and the output terminal of the comparator detection circuit is electrically connected to a control terminal of the rectifier circuit;
the receiver circuit comprises a receive coil coupled to a transmit coil, and is configured to receive an alternating current (AC) voltage via the receive coil, and transmit the AC voltage to the rectifier circuit; and
the rectifier circuit is configured to convert the AC voltage to a direct current (DC) voltage.

8. The wireless charging receiver according to claim 7, wherein the precision reference voltage adjustment circuit comprises a switch assembly, a voltage sampling circuit, a reference circuit, a comparator circuit, and a logic processing circuit; wherein
a first terminal of the switch assembly is configured to receive the voltage to be measured upon completion of the power transistor, a control terminal of the switch assembly is electrically connected to the output terminal of the logic control circuit, a second terminal of the switch assembly is electrically connected to a first input terminal of the comparator circuit, a first terminal of the voltage sampling circuit is electrically connected between the second terminal of the switch assembly and the first input terminal of the comparator circuit, a second terminal of the voltage sampling circuit and a first terminal of the reference circuit are both grounded, a second terminal of the reference circuit is electrically connected to a second input terminal of the comparator circuit, an output terminal of the comparator circuit is electrically connected to an input terminal of the logic processing circuit, and an output terminal of the logic processing circuit is electrically connected to the first input terminal of the comparator detection circuit;
the logic control circuit is configured to transmit the enable signal within the preceding clock cycle to the switch assembly, wherein the switch assembly is turned on under the effect of the enable signal within the preceding clock cycle;
the voltage sampling circuit is configured to, upon turn-on of the switch assembly, sample the voltage to be measured upon completion of turn-off of the power transistor to acquire a sampled voltage, transmit the sampled voltage to the comparator circuit, wherein the sampled voltage is related to the voltage to be measured upon completion of turn-off of the power transistor;
the reference circuit is configured to transmit a reference voltage to the comparator circuit, wherein the reference voltage is used for determining whether the power transistor is turned off on time in response to the turn-off control signal within the preceding clock cycle;
the comparator circuit is configured to acquire a digital signal based on the sampled voltage and the reference voltage, and transmit the digital signal to the logic processing circuit; and
the logic processing circuit is configured to generate the adjustment signal within the subsequent clock cycle based on the digital signal.

9. The wireless charging receiver according to claim 8, wherein the logic control circuit is configured to increase the precision reference voltage within the preceding clock cycle using the adjustment signal within the subsequent clock cycle in a case that the digital signal indicates that the voltage to be measured upon completion of turn-off of the power transistor is greater than the reference voltage; or
the logic control circuit is configured to decrease the precision reference voltage within the preceding clock cycle using the adjustment signal within the subsequent clock cycle in a case that the digital signal indicates that the voltage to be measured upon completion of turn-off of the power transistor is less than the reference voltage.

10. The wireless charging receiver according to claim 8, wherein the comparator circuit comprises a comparator;
wherein a first input terminal of the comparator is electrically connected to an output terminal of the voltage sampling circuit, a second input terminal of the comparator is electrically connected to the second terminal of the reference circuit, and an output terminal of the comparator is electrically connected to the input terminal of the logic processing circuit.

11. The wireless charging receiver according to claim 8, wherein the voltage sampling circuit comprises a first capacitor; wherein a first terminal of the first capacitor is electrically connected between the second terminal of the switch assembly and the first input terminal of the comparator circuit, and a second terminal of the first capacitor is grounded.

12. The wireless charging receiver according to claim 7, wherein the comparator detection circuit comprises a zero-crossing detection comparator; wherein a first input terminal of the zero-crossing detection comparator is configured to receive the precision reference voltage, a second input terminal of the zero-crossing detection comparator is configured to receive the voltage to be measured in response to turn-on of the power transistor, and an output terminal of the zero-crossing detection comparator is electrically connected to the input terminal of the logic control circuit.

13. A switching power supply, comprising: an operational amplifier circuit, a pulse width modulation comparator circuit, a control circuit, a first driver circuit, a second driver circuit, a high-side power transistor, a low-side power transistor, a freewheeling inductor, a second capacitor, and a zero-crossing detection circuit; wherein the zero-crossing detection circuit comprises: a comparator detection circuit, a precision reference voltage adjustment circuit, and a logic control circuit; wherein
a first input terminal of the comparator detection circuit is configured to receive a precision reference voltage, a second input terminal of the comparator detection circuit is configured to receive a voltage to be measured in response to turn-on of a power transistor of a wireless charging receiver or a switching power supply, an input terminal of the precision reference voltage adjustment circuit is configured to receive a voltage to be measured upon completion of turn-off of the power transistor, an output terminal of the comparator detection circuit is electrically connected to an input terminal of the logic control circuit, an output terminal of the logic control circuit is electrically connected to a control terminal of the precision reference voltage adjustment circuit, and an output terminal of the precision reference voltage adjustment circuit is electrically connected to the first input terminal of the comparator detection circuit;
the comparator detection circuit is configured to, with respect to two adjacent clock cycles, acquire a turn-off control signal within a preceding clock cycle of the two adjacent clock cycles based on a precision reference voltage within the preceding clock cycle and the voltage to be measured in response to turn-on of the power transistor, and transmit the turn-off control signal within the preceding clock cycle to the logic control circuit, wherein the turn-off control signal within the preceding clock cycle is used for controlling the power transistor to be turned off;
the logic control circuit is configured to acquire an enable signal within the preceding clock cycle based on the turn-off control signal within the preceding clock cycle, and transmit the enable signal within the preceding clock cycle to the precision reference voltage adjustment circuit;
the precision reference voltage adjustment circuit is configured to, under an effect of the enable signal within the preceding clock cycle, acquire an adjustment signal within a subsequent clock cycle of the two adjacent clock cycles based on changes of the voltage to be measured upon completion of turn-off of the power transistor, and transmit the adjustment signal within the subsequent clock cycle to the comparator detection circuit;
the comparator detection circuit is configured to adjust the precision reference voltage within the preceding clock cycle based on the adjustment signal within the subsequent clock cycle to acquire a precision reference voltage within the subsequent clock cycle, and acquire a turn-off control signal within the subsequent clock cycle based on the precision reference voltage within the subsequent clock cycle and the voltage to be measured in response to turn-on of the power transistor, wherein the turn-off control signal within the subsequent clock cycle is used for controlling the power transistor to be turned off;
a first input terminal of the operational amplifier circuit is configured to receive a reference signal, a second input terminal of the operational amplifier circuit is configured to receive a feedback signal, an output terminal of the operational amplifier circuit is electrically connected to a first input terminal of the pulse width modulation comparator circuit, a second terminal of the pulse width modulation comparator circuit is configured to receive a triangle wave signal, an output terminal of the pulse width modulation comparator circuit and the output terminal of the comparator detection circuit are both electrically connected to an input terminal of the control circuit, an output terminal of the control circuit is electrically connected to an input terminal of the first driver circuit and an input terminal of the second driver circuit, an output terminal of the first driver circuit is electrically connected to a control terminal of the high-side power transistor, an output terminal of the second driver circuit is electrically connected to a control terminal of the low-side power transistor, a first terminal of the high-side power transistor is configured to receive a power supply voltage, a second terminal of the high-side power transistor is electrically connected to a first terminal of the low-side power transistor, the second input terminal of the comparator detection circuit, the input terminal of the precision reference voltage adjustment circuit, and a first terminal of the freewheeling inductor are all electrically connected between the second terminal of the high-side power transistor and the first terminal of the low-side power transistor, a second terminal of the freewheeling inductor is electrically connected to a first terminal of the second capacitor, and a second terminal of the low-side power transistor and a second terminal of the second capacitor are both grounded;
the operational amplifier circuit is configured to transmit an output signal of the operational amplifier circuit to the pulse width modulation comparator circuit based on the reference signal and the feedback signal;
the pulse width modulation comparator circuit is configured to transmit a pulse width modulation signal to the control circuit based on the output signal of the operational amplifier circuit and the triangle wave signal;
the zero-crossing detection circuit is configured to acquire a voltage to be measured from the high-side power transistor or the low-side power transistor, and transmit a turn-off control signal to the control circuit based on the precision reference voltage and the voltage to be measured, wherein the voltage to be measured comprises a difference between a voltage at the second terminal of the high-side power transistor and a zero voltage or a difference between a voltage at the first terminal of the low-side power transistor and the zero voltage;
the control circuit is configured to transmit a turn-on or turn off control signal to the first driver circuit and the second driver circuit based on the pulse width modulation signal and the turn-off control signal;
the first driver circuit is configured to control turn-on or turn-off of the high-side power transistor based on the turn-on or turn-off control signal; and
the second driver circuit is configured to control turn-on or turn-off of the low-side power transistor based on the turn-on or turn-off control signal.

14. The switching power supply according to claim 13, wherein the precision reference voltage adjustment circuit comprises a switch assembly, a voltage sampling circuit, a reference circuit, a comparator circuit, and a logic processing circuit; wherein
a first terminal of the switch assembly is configured to receive the voltage to be measured upon completion of the power transistor, a control terminal of the switch assembly is electrically connected to the output terminal of the logic control circuit, a second terminal of the switch assembly is electrically connected to a first input terminal of the comparator circuit, a first terminal of the voltage sampling circuit is electrically connected between the second terminal of the switch assembly and the first input terminal of the comparator circuit, a second terminal of the voltage sampling circuit and a first terminal of the reference circuit are both grounded, a second terminal of the reference circuit is electrically connected to a second input terminal of the comparator circuit, an output terminal of the comparator circuit is electrically connected to an input terminal of the logic processing circuit, and an output terminal of the logic processing circuit is electrically connected to the first input terminal of the comparator detection circuit;
the logic control circuit is configured to transmit the enable signal within the preceding clock cycle to the switch assembly, wherein the switch assembly is turned on under the effect of the enable signal within the preceding clock cycle;
the voltage sampling circuit is configured to, upon turn-on of the switch assembly, sample the voltage to be measured upon completion of turn-off of the power transistor to acquire a sampled voltage, transmit the sampled voltage to the comparator circuit, wherein the sampled voltage is related to the voltage to be measured upon completion of turn-off of the power transistor;
the reference circuit is configured to transmit a reference voltage to the comparator circuit, wherein the reference voltage is used for determining whether the power transistor is turned off on time in response to the turn-off control signal within the preceding clock cycle;
the comparator circuit is configured to acquire a digital signal based on the sampled voltage and the reference voltage, and transmit the digital signal to the logic processing circuit; and
the logic processing circuit is configured to generate the adjustment signal within the subsequent clock cycle based on the digital signal.

15. The switching power supply according to claim 14, wherein the logic control circuit is configured to increase the precision reference voltage within the preceding clock cycle using the adjustment signal within the subsequent clock cycle in a case that the digital signal indicates that the voltage to be measured upon completion of turn-off of the power transistor is greater than the reference voltage; or
the logic control circuit is configured to decrease the precision reference voltage within the preceding clock cycle using the adjustment signal within the subsequent clock cycle in a case that the digital signal indicates that the voltage to be measured upon completion of turn-off of the power transistor is less than the reference voltage.

16. The switching power supply according to claim 14, wherein the comparator circuit comprises a comparator;
wherein a first input terminal of the comparator is electrically connected to an output terminal of the voltage sampling circuit, a second input terminal of the comparator is electrically connected to the second terminal of the reference circuit, and an output terminal of the comparator is electrically connected to the input terminal of the logic processing circuit.

17. The switching power supply according to claim 14, wherein the voltage sampling circuit comprises a first capacitor; wherein a first terminal of the first capacitor is electrically connected between the second terminal of the switch assembly and the first input terminal of the comparator circuit, and a second terminal of the first capacitor is grounded.

18. The switching power supply according to claim 13, wherein the comparator detection circuit comprises a zero-crossing detection comparator; wherein a first input terminal of the zero-crossing detection comparator is configured to receive the precision reference voltage, a second input terminal of the zero-crossing detection comparator is configured to receive the voltage to be measured in response to turn-on of the power transistor, and an output terminal of the zero-crossing detection comparator is electrically connected to the input terminal of the logic control circuit.
